(19) United States
(12) Patent Application Publication
(10) Pub. No.: US 2012/0250789 A1
(43) Pub. Date: Oct. 4, 2012

(54) GENERATING A MODULATED SIGNAL FOR A TRANSMITTER

(76) Inventors: Zhondga Wang, Sunnyvale, CA (US); Sai Chu Wong, San Jose, CA (US); Yunteng Huang, Palo Alto, CA (US)

(21) Appl. No.: 13/077,385

(22) Filed: Mar. 31, 2011

(51) Int. Cl. H04L 25/03; H03B 28/00

(52) U.S. Cl. 375/296; 327/129

(57) ABSTRACT

A technique includes generating an angle modulated square wave signal and progressively filtering the angle modulated square wave signal in a transmitter using a plurality of low pass filters to produce a modulated sinusoidal signal to drive an antenna. The technique includes programming the transmitter to tune a corner frequency of the filtering to a frequency within a range of frequencies selectable using the programming, based on a carrier frequency associated with the modulated sinusoidal signal.

### BACKGROUND

This disclosure generally relates to generating a modulated signal for a transmitter.

For purposes of wirelessly transmitting data, a relatively high frequency carrier signal may be modulated with the data to produce a modulated signal to drive an antenna. One type of modulation is angle modulation, which involves modulating the angle of the carrier signal. The angle modulation may involve modulating the frequency of the carrier signal (called “frequency modulation (FM)”) or modulating the phase of the carrier signal (called “phase modulation (PM)”).

### SUMMARY

In an exemplary embodiment, a technique includes generating an angle modulated square wave signal and progressively filtering the angle modulated square wave signal in a transmitter using a plurality of serially coupled low pass filters to produce a modulated sinusoidal signal to drive an antenna. The technique includes programming the transmitter to tune a corner frequency of the filtering to a frequency within a range of frequencies selectable using the programming, based on a carrier frequency associated with the modulated sinusoidal signal.

In another exemplary embodiment, a transmitter includes a modulator and a plurality of serially coupled low pass filters. The modulator is adapted to generate an angle modulated square wave signal, and the filters progressively filter the angle modulated square wave signal to produce a modulated sinusoidal signal to drive an antenna. The filters are collectively associated with a corner frequency, and the filters are adapted to be programmed to tune the corner frequency to a frequency within a range of frequencies selectable by the programming, based on a carrier frequency associated with the modulated sinusoidal signal.

In yet another exemplary embodiment, an apparatus includes an integrated circuit that includes a modulator and a plurality of serially coupled low pass filters. The modulator is adapted to generate an angle modulated square wave signal. The filters are collectively associated with a corner frequency and are adapted to progressively filter the angle modulated square wave signal to produce a modulated sinusoidal signal to drive an antenna and be programmed to tune the corner frequency to a frequency within a range of frequencies selectable by the programming, based on a carrier frequency associated with the modulated sinusoidal signal.

Advantages and other features of the disclosed concepts will become apparent from the following drawing, description and claims.

### BRIEF DESCRIPTION OF THE DRAWING

FIG. 1 is a schematic diagram of a wireless device according to an exemplary embodiment.

FIG. 2 is a schematic diagram of a transmitter of the wireless device of FIG. 1 according to an exemplary embodiment.

FIG. 3 is a flow diagram depicting a technique to generate a modulated sinusoidal signal to drive an antenna according to an exemplary embodiment.

FIG. 4 is a schematic diagram of an output circuit of the transmitter of FIG. 2 according to an exemplary embodiment.

FIG. 5 depicts a gain versus frequency plot for each of the filters of the output circuit of FIG. 4 according to an exemplary embodiment.

FIG. 6 depicts overall gain versus frequency plot for the filters of FIG. 4 according to an exemplary embodiment.

FIG. 7 is a schematic diagram of an active resistor-capacitor (R-C) filter according to an exemplary embodiment.

FIG. 8 is a schematic diagram of a capacitor array of the output circuit of FIG. 4 according to an exemplary embodiment.

FIG. 9 is a schematic diagram of a resistor array of the output circuit of FIG. 4 according to an exemplary embodiment.

### DETAILED DESCRIPTION

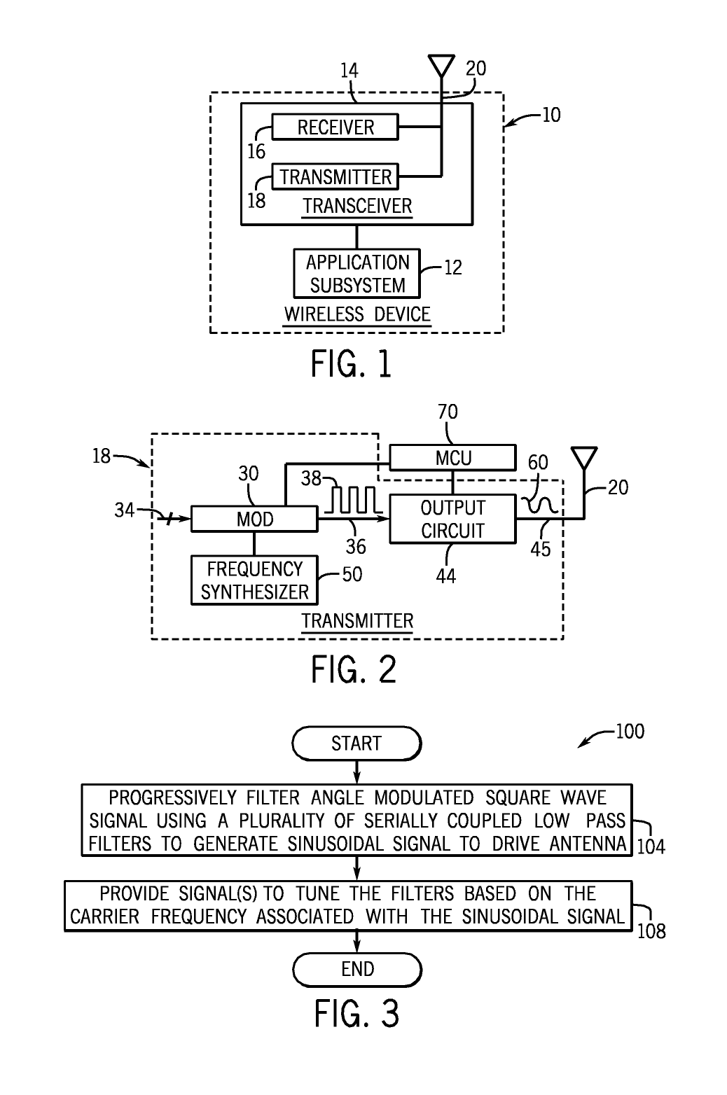

Referring to FIG. 1, a wireless device 10 may be used in a number of different applications for purposes of communicating data over a wireless link. As non-limiting examples, the wireless device 10 may be a personal computer (PC) peripheral; a wireless toy; a remote keyless entry; an industrial control; a home automation controller, sensor or slave device; a sensor network; etc. In general, the wireless device 10 includes an application subsystem 12, which tailors the wireless device 10 for its specific application and may, for example, form a user interface for the device 10. In general, the application subsystem 12 performs various application processing tasks relating to the application in which the wireless device 10 is employed, and these tasks may involve communicating data to a transceiver 14 of the wireless device 10 to be transmitted over a wireless link and receiving data from the transceiver 14, which was received from the wireless link. It is noted that in other exemplary embodiments, the wireless device 10 may only transmit data and not include a receiver. Thus, many variations are contemplated and are within the scope of the appended claims.

The transceiver 14 for the exemplary embodiment depicted in FIG. 1 includes a transmitter 18 that is coupled to an antenna 20 for purposes of transmitting data over the wireless link. In this manner, the transmitter 18 modulates a carrier signal with data to be transmitted and provides the resulted modulated carrier signal to the antenna 20, which radiates electromagnetic energy in response to the signal to transmit the data over the wireless link. The transceiver 14 for the embodiment depicted in FIG. 1 also includes a receiver 16, which is coupled to the antenna 20 for purposes of receiving a modulated carrier signal that is indicative of data that is received from the wireless link. The receiver 16 demodulates the modulated carrier signal to recover the transmitted data and provides this data to the application subsystem 12.

In accordance with other exemplary embodiments, the receiver 16 and the transmitter 18 may be coupled to separate antennas of the wireless device 10. Moreover, in accordance with some exemplary embodiments, the wireless device 10 may include multiple antennas 20 that the wireless device 10 selectively couples to the transmitter 18, depending on one of multiple transmission frequency bands that may be selected for the communication over the wireless link. In a similar manner, in accordance with some exemplary embodiments, the wireless device 10 may include multiple antennas 20 that the wireless device 10 selectively couples to the receiver 16, depending on one of multiple transmission frequency bands that may be selected for communication over the wireless link.

Referring to FIG. 2, in accordance with some exemplary embodiments, the transmitter 18 includes various components, which may be part of the same integrated circuit (may be fabricated in the same die or on separate dies of the same semiconductor package, for example). In some exemplary embodiments, the entire transmitter 18 may be fabricated on a single die and as such, may be part of a single integrated circuit.

The transmitter 18 includes a modulator 30, which receives data from the application subsystem 12 via input terminals 34. In general, the modulator 30 modulates a carrier signal (provided by a frequency synthesizer 50, for example) with the data that is provided by the application subsystem 12 for purposes of creating a modulated signal.

More specifically, in accordance with some exemplary embodiments, the modulator 30 performs angle modulation, such as phase modulation (PM) or frequency modulation (FM), on a square wave carrier signal to produce a corresponding angle modulated square wave signal 38 on an output terminal 36 of the modulator 30.

The angle modulated square wave signal 38, in turn, is received by an output circuit 44 of the transmitter 18 for purposes of producing the corresponding signal that is provided to the antenna 20. In this manner, as described herein, the output circuit 44 filters harmonics of the angle modulated square wave signal 38 to produce an angle modulated sinusoidal signal 60 (i.e., a signal that is generally equivalent to a signal formed by angle modulating a sinusoidal carrier signal). The angle modulated sinusoidal signal 60, in general, contains a modulated carrier frequency and substantially small or no harmonic energy (i.e., energy that is at multiple frequencies of the carrier frequency).

Due to the removal of the harmonics from the angle modulated square wave signal 38, unwanted spurs that are otherwise attributable to coupling between circuitry communicating the angle modulated square wave 38 and the frequency synthesizer 50 of the transmitter 18 are avoided. Moreover, the above-described filtering by the output circuit 44 band limits the frequencies that are being transmitted from the antenna 20.

As depicted in FIG. 2, in accordance with some exemplary embodiments, a microcontroller unit (MCU) 70, such as an MCU of the wireless device 10 (see FIG. 1) may execute instructions for purpose of responding to received signals and generally generating the signals that control operations of the modulator 30 as well as program the filtering parameters of the output circuit 44, as further described below. The modulator 30 and/or output circuit 44 may be controlled and/or programmed by other hardware, in accordance with other exemplary embodiments.

Referring to FIG. 3 in conjunction with FIG. 2, in accordance with some exemplary embodiments, the output circuit 44 performs a technique 100 that is generally depicted in FIG. 3. According to the technique 100, the angle modulated square wave signal 38 is progressively filtered by a plurality of serially coupled low pass filters to generate the modulated sinusoidal signal 60, pursuant to block 104. The technique 100 further includes providing one or more signals to tune the filters of the output circuit 44 based on the carrier frequency associated with the modulated sinusoidal signal, pursuant to block 108.

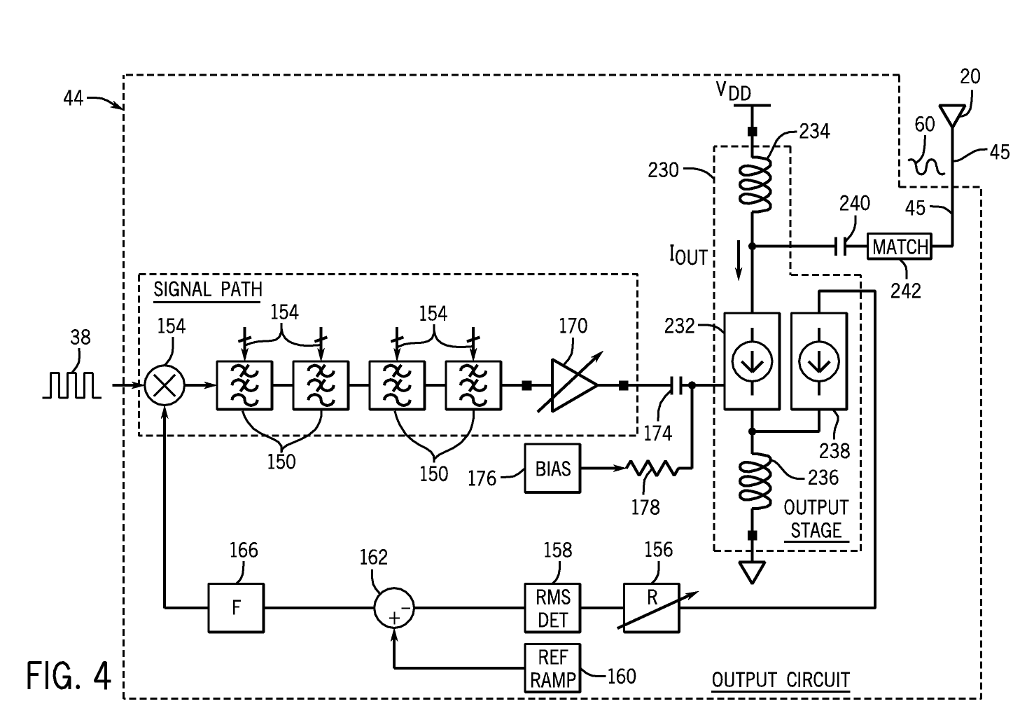

FIG. 4 generally depicts a schematic diagram of the output circuit 44, in accordance with some exemplary embodiments. In general, the output circuit 44 includes an arrangement of serially coupled low pass filters 150 in an incoming signal path 151 of the incoming angle modulated square wave 38 to collectively filter out the angle modulated square wave's harmonics. More specifically, in accordance with some exemplary embodiments, each filter 150 is a first order low pass resistor-capacitor (R-C) filter, and the combination of filters 150 collectively forms a higher order low pass filter to filter out the harmonics of the angle modulated square wave signal 38.

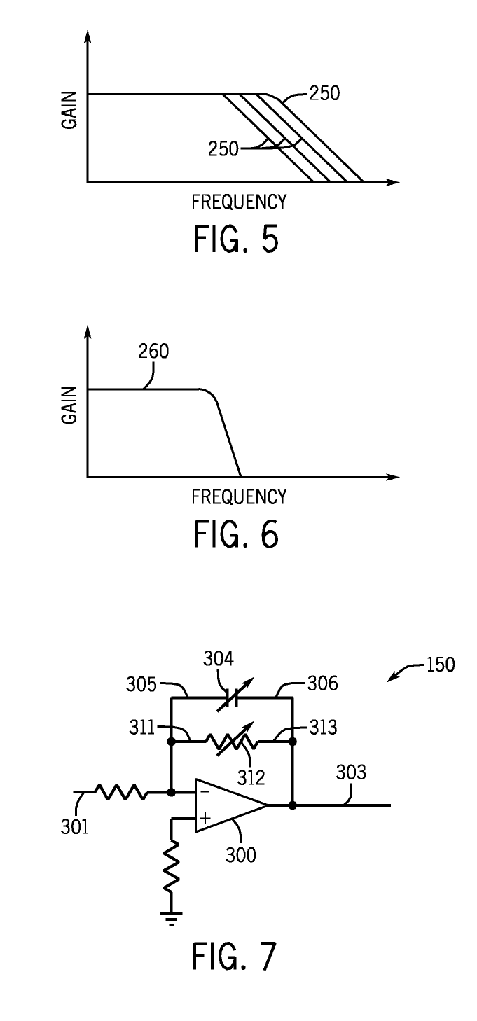

Referring to FIG. 5 in conjunction with FIG. 4, as a non-limiting example, each filter 150 may have an associated gain versus frequency profile 250, and the 3 decibel (dB) roll off, or corner, frequencies f₁, f₂, f₃ and f₄ of the profiles 250 are purposefully staggered, as depicted in FIG. 5. Due to this arrangement, the filters 150 collectively form a higher order filter having a gain versus frequency profile 260, as depicted in FIG. 6. Thus, as a non-limiting example, for first order filters, the filters 150 individually have a 20 decibel (dB) roll off, with the collective filtering by all of the filters 150 producing a 80 dB roll off with a 3 db corner frequency f_{R} collectively produced by the filters 150, as depicted in FIG. 6.

As depicted in FIG. 4, the corresponding angle modulated sinusoidal signal that is produced by the chain of filters 150 is provided to the input terminal of a programmable gain amplifier (PGA) 170 of the output circuit 44. The PGA 170 amplifies the modulated sinusoidal signal that is received from the filters 150 and furnishes the resulting amplified signal to a DC filtering capacitor 174. The capacitor 174 removes the DC biasing from the signal to produce an input modulated sinusoidal signal for an output stage 230 of the output circuit 44.

In general, the output stage 230 generates an output current (called “I_{OUT}” in FIG. 4), which is DC filtered through a DC blocking capacitor 240 to produce a corresponding modulated sinusoidal current signal that is provided to an antenna matching circuit 242 that, in turn, provides the modulated sinusoidal signal 60 to drive the antenna 20. In general, the output stage 230 includes a current amplifier 232, which produces the I_{OUT} signal in response to the amplified signal that is provided by the PGA 170. As illustrated in FIG. 4, the amplifier 232 may be coupled to a positive voltage supply (called “V_{DD}” in FIG. 4) through inductor 234 and may coupled to ground through a parasitic inductor 236 (parasitic inductance created by bond wire inductance, for example).

For purposes of regulating the output power of the transmitter 18, the output circuit 44 may include a gain control feedback loop, which includes a current source 238 that samples the current in the output stage 230 and provides the sampled current to a resistor 156 (a programmable or variable resistor, for example). A signal strength/power detection circuit 158 receives the signal from the resistor 156 to produce a corresponding signal indicative of the sensed power. An adder 162 of the gain control feedback loop algebraically sums the signal from the circuit 158 with a reference ramp signal that is provided by a reference ramp circuit 160 to produce a corresponding control signal that is filtered (via a filter 166) to produce a corresponding control signal for a multiplier 153.

As also illustrated in FIG. 4, the output circuit 44 may further include a bias network, which is formed from a bias circuit 176 that is coupled to the output stage 230 via a coupling resistor 178. The bias current 176 may be used to bias the output stage 230 to operate in a particular amplifier class mode of operation. For example, the bias circuit 174 may bias the input signal to the output stage 230 to cause the output stage 230 to operate in a class A mode of operation such that the modulated sinusoidal signal 60 is not clipped at either the V_{DD} positive supply level or ground. Alternatively, the biasing may configure the output stage 230 to operate in another mode of operation, such as a class B mode in which the modulated sinusoidal signal 60 is biased to clip every half cycle of the modulated sinusoidal signal 60. As yet another example, the bias circuit 176 may bias the output stage 230 to operate in a class AB mode of operation. Thus, many variations are contemplated and are within the scope of the appended claims.

In accordance with some exemplary embodiments, the filter 150 may be a linearized low gain active resistor-capacitor (R-C) that has a programmable roll off, or corner frequency, such that the corner frequency may be tuned to any frequency in a wide frequency range (a range of 160 Megahertz (MHz) to approximately 1 Gigahertz (GHz), in accordance with some exemplary embodiments). As a result, the collective low pass filter formed from the serial chain of low pass filters 150 may likewise be programmed such that the corner frequency of the collective low pass filter may be tuned to any frequency in the same wide frequency range (a range of 160 MHz to approximately 1 GHz, in accordance with some exemplary embodiments). The resistances and capacitances of the serial chain of filters 150 may be programmed to permit operation in a wide range of radio frequency (RF) frequencies and at the same time, a relatively fine frequency granularity due to the progressive filtering. As a more specific, non-limiting example, the overall frequency ranges may be subdivided by a predefined number (at least twenty, for example) of uniform or non-uniform steps so that the collective corner frequency of the filters 150 may be finely tuned to one of the frequencies defined by the steps in the relatively coarse 160 MHz to 1 GHz frequency range. In general, the capacitances of the filters 150 are programmed using signals 154, and the resistances of the filters 150 are programmed using signals 155.

Referring to FIG. 7 in conjunction with FIG. 4, in accordance with an exemplary embodiment, the filter 150 includes a differential amplifier that is formed from a differential pair of n-channel metal-oxide-semiconductor field-effect-transistors (nMOSFETs) 314 and 316. The gate terminal of the nMOSFET 314 receives a DC-filtered version of a positive differential input signal (called “V_{IP},” in FIG. 7) due to the filtering of a DC-blocking capacitor 306; and the gate terminal of the nMOSFET 316 receives a filtered version of the negative differential input signal (called “V_{IN},” in FIG. 7), due to the filtering of a DC-blocking capacitor 307. The gate terminals of the nMOSFETs 314 and 316 are coupled by respective resistors 315 and 317 to a bias signal (called “DC_BIAS1” in FIG. 7).

The source terminal of the nMOSFET 314 is coupled to a node 321, and the source terminal of the nMOSFET 316 is coupled to a node 323. As shown in FIG. 7, a variable resistor 312c is coupled between the nodes 321 and 323. Moreover, a current source 320 is coupled between the node 321 and ground, and a current source 322 is coupled between the node 323 and ground.

The drain terminal of the nMOSFET 314 is coupled to a node 324, and the drain terminal of the nMOSFET 316 is coupled to a node 326. As shown in FIG. 7, a variable capacitor 304 is coupled between the nodes 334 and 336; and a variable resistor 312a is coupled between the node 324 and a positive supply voltage (called “V_{DD},” in FIG. 7), and a variable resistor 312b is coupled between the node 326 and the V_{DD} power supply.

For purposes of tuning the corner frequency of the filter 150, the resistances of the resistors 312a, 312b and 312c are tuned via resistor codes, and the capacitance of the capacitor 304 is tuned via a capacitor code. In this manner, in accordance with an exemplary embodiment, the resistor codes for each one of the resistors 312a, 312b and 312c controls a set of switch signals 155 (see FIG. 4), which, in turn, control the coupling of resistors together to form the overall resistance of the resistor 312a, 312b and 312c. In a similar manner, in accordance with an exemplary embodiment, the capacitor codes for the capacitor 304 controls a set of switch signals 154 (see FIG. 4), which, in turn, control the coupling of capacitors together to form the overall capacitance of the capacitor 304.

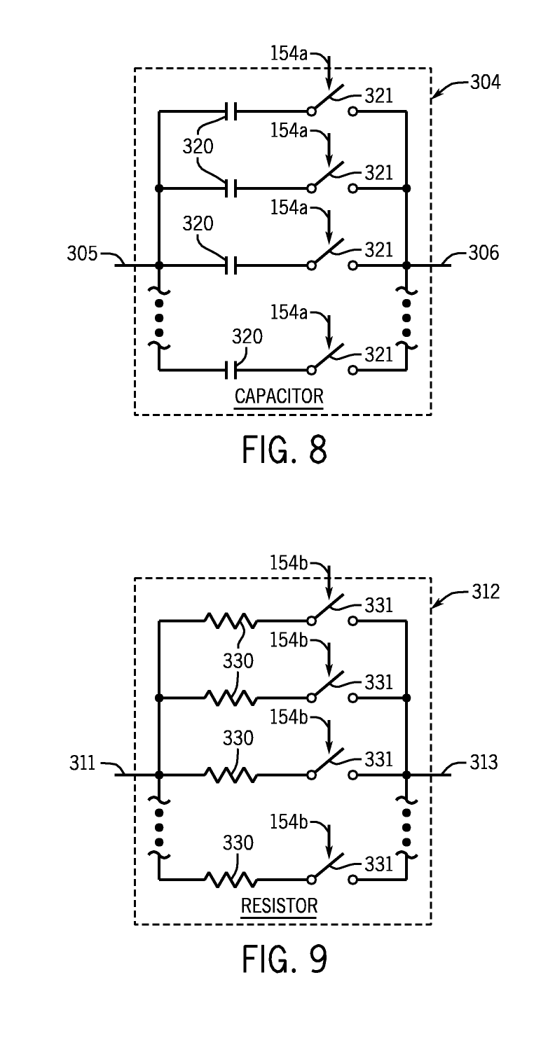

As a more specific example, FIG. 8 depicts the capacitor 304 in accordance with an exemplary embodiment. As shown, the capacitor 304 is formed from capacitors that are selectively coupled together by switches 331, and each of these switches 331 is controlled by a different associated switch signal 154 (switch signals 154₁, 154₂ . . . 154_{N}, being depicted in FIG. 8 as examples). Each switch 331, under the control of its associated switch signal 154, regulates the addition of an incremental capacitance to the overall capacitance of the capacitor 304. In other words, when switch 331 is closed, the overall capacitance of the capacitor 304 increases, and when the switch 331 is opened, the overall capacitance of the capacitor 304 decreases.

Each switch 331 is coupled between a terminal of a capacitor 342 and a terminal of a capacitor 346. The other terminals of the capacitors 342 and 346 are coupled to the overall terminals 324 and 326, respectively, of the capacitor 304. Differential biasing is provided by resistors 340 and 344 that are coupled to a bias signal (called “DC_BIAS2,” in FIG. 8).

Referring to FIG. 9, in accordance with exemplary embodiments, each of the resistors 312a, 312b and 312c (see FIG. 7) may have a design similar to a resistor 312. As depicted in FIG. 9, the resistor 312 may be formed from multiple resistors 330 that are selectively coupled in parallel with other resistors 330 to form the overall resistance for the resistor 312 via associated switches 337. In this manner, each of resistors 330 may be selectively coupled between overall terminals 305 and 306 of the resistor 312 in response to the associated switch 337 receiving the appropriate signal 155 (signals 155₁, 155₂ 155₃ . . . 155_{N}, as being depicted in FIG. 9, as non-limiting examples). Thus, when a switch 331 is closed, the overall resistance of the resistor 312 decreases due to the parallel coupling of an additional resistor 303; and when a switch 331 is opened, the overall resistance of the resistor 312 increases due to the removal of a parallel resistor 303.

In accordance with exemplary embodiments, the capacitor 304 and resistor 312 may be built on lower layers of metal or semiconductor layers of the die that contain the elements of the transmitter 18. Moreover, components of the capacitor 304 and resistor 312 may be placed beneath shielding metal to avoid coupling signals from the capacitor 304 and/or resistor 312 to other components of the transmitter 18, such as an on-chip inductor of the frequency synthesizer 50 (see FIG. 2), for example.

While the present invention has been described with respect to a limited number of embodiments, those skilled in the art, having the benefit of this disclosure, will appreciate numerous modifications and variations therefrom. It is intended that the appended claims cover all such modifications and variations as fall within the true spirit and scope of this present invention.

What is claimed is:

1. A method comprising:
generating an angle modulated square wave signal;
progressively filtering the angle modulated square wave signal in a transmitter using a plurality of serially coupled low pass filters to produce a modulated sinusoidal signal to drive an antenna; and
programming the transmitter to tune a corner frequency of the filtering to a frequency within a range of frequencies selectable using the programming, based on a carrier frequency associated with the modulated sinusoidal signal.

2. The method of claim 1, wherein the range of frequencies comprise a range of frequencies from 160 Megahertz to 1 Gigahertz.

3. The method of claim 2, further comprising subdividing the range by at least twenty frequency steps, wherein the programming comprises programming the transmitter to tune the corner frequency to one of a plurality of frequencies defined by the steps.

4. The method of claim 1, wherein the low pass filters comprise resistor-capacitor low pass filters and the act of programming comprises providing at least one signal to tune capacitances of the filters and providing at least one signal to tune resistances of the filters.

5. The method of claim 1, wherein the act of progressively filtering comprises communicating the angle modulated square wave signal through active filters.

6. The method of claim 1, wherein each of the filters has an associated corner frequency, the programming further comprising regulating the associated corner frequencies to control a roll off characteristic of the filtering.

7. The method of claim 1, wherein each of the filters comprises a resistor-capacitor low pass filter, the low pass filters comprise resistor-capacitor low pass filters and the act of programming comprises, for each of the filters, providing at least one signal to selectively couple together capacitances to form a capacitance of the filter.

8. The method of claim 1, wherein each of the filters comprises a resistor-capacitor low pass filter, the low pass filters comprise resistor-capacitor low pass filters and the act of programming comprises, for each of the filters, providing at least one signal to selectively couple together resistors to form a resistance of the filter.

9. A transmitter comprising:
a modulator adapted to generate an angle modulated square wave signal; and
a plurality of serially coupled low pass filters to progressively filter the angle modulated square wave signal to produce a modulated sinusoidal signal to drive an antenna,
wherein the plurality of serially coupled low pass filters are collectively associated with a corner frequency, and the filters are adapted to be programmed to tune the corner frequency to a frequency within a range of frequencies selectable by the programming, based on a carrier frequency associated with the modulated sinusoidal signal.

10. The transmitter of claim 9, wherein the range of frequencies comprise a range of frequencies from 160 Megahertz to 1 Gigahertz.

11. The transmitter of claim 10, wherein the range is subdivided by at least twenty frequency steps, wherein the filters are adapted to be programmed to tune the corner frequency to one of a plurality of frequencies defined by the steps.

12. The transmitter of claim 9, wherein the angle modulated square wave signal comprises a frequency modulated square wave signal or a phase modulated square wave signal.

13. The transmitter of claim 9, wherein the filters comprise active filters.

14. The transmitter of claim 9, wherein at least one of the filters comprises:
resistors; and
switches adapted to selectively couple the resistors to a signal path of the filter to set a corner frequency of the filter.

15. The transmitter of claim 9, wherein at least one of the filters comprises:
capacitors; and
switches adapted to selectively couple the capacitors to a signal path of the filter to set a corner frequency of the filter.

16. The transmitter of claim 9, wherein at least one of the filters comprises capacitors, resistors, first switches and second switches, the transmitter further comprising a controller adapted to set a corner frequency of the filter by:
regulating switching states of the first switches to selectively couple the capacitors to a signal path of the filter; and
regulating switching states of the second switches to selectively couple the resistors to a signal path of the filter.

17. An apparatus comprising:
an integrated circuit comprising a modulator and a plurality of low pass filters,
wherein the modulator is adapted to generate an angle modulated square wave signal, and the low pass filters are collectively associated with a corner frequency and are adapted to:
progressively filter the angle modulated square wave signal to produce a modulated sinusoidal signal to drive an antenna; and
be programmed to tune the corner frequency to a frequency within a range of frequencies selectable by the programming, based on a carrier frequency associated with the modulated sinusoidal signal.

18. The apparatus of claim 17, wherein the integrated circuit further comprises a receiver coupled to the antenna.

19. The apparatus of claim 17, wherein each of the filters has an associated corner frequency, and the associated corner frequencies are different.

20. The apparatus of claim 17, wherein at least one of the filters comprises capacitors, resistors, first switches and second switches, the apparatus further comprising a controller adapted to set a corner frequency of the filter by:
regulating switching states of the first switches to selectively couple the capacitors to a signal path of the filter; and
regulating switching states of the second switches to selectively couple the resistors to a signal path of the filter.
